(19) United States
(12) Patent Application Publication
(10) Pub. No.: US 2010/0101730 A1
(43) Pub. Date: Apr. 29, 2010

(54) SUBSTRATE PROCESSING APPARATUS

(75) Inventors: Kyu Jin CHOI, Gyeonggi-Do (KR); Sung Min NA, Gyeonggi-Do (KR); Euy Kyu LEE, Gyeonggi-Do (KR); Yong Han JEON, Gyeonggi-Do (KR); Cheol Hoon YANG, Gyeonggi-Do (KR); Tae Wan LEE, Gyeonggi-Do (KR); Uk HWANG, Gyeonggi-Do (KR); Sun Kee KIM, Seoul (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-Do (KR)

(21) Appl. No.: 12/603,582

(22) Filed: Oct. 21, 2009

(30) Foreign Application Priority Data
Oct. 29, 2008 (KR) 10-2008-0106527
Oct. 8, 2009 (KR) 10-2009-0095791
Oct. 8, 2009 (KR) 10-2009-0095792

(51) Int. Cl. H01L 21/465; H01L 21/687; B05C 13/02

(52) U.S. Cl. 156/345.55; 269/57; 118/500; 257/E21.485

(57) ABSTRACT

A substrate processing apparatus, which is designed to prevent the wobbling of a rotational shaft rotating, is provided. The substrate includes a rotation shaft and a connecting member. A unit is disposed between the rotational shaft and the connecting member to make the rotational shaft and the connecting member close-contact each other or a unit is disposed under the rotational shaft to prevent the wobbling of the rotational shaft.

### CROSS-REFERENCE TO RELATED APPLICATION

This application claims priority to Korean Patent Application Nos. 10-2008-0106527 filed on Oct. 29, 2008, 10-2009-0095791 filed on Oct. 8, 2009 and 10-2009-0095792 filed on Oct. 8, 2009, and all the benefits accruing therefrom under 35 U.S.C. §119, the contents of which are incorporated by reference in their entirety.

### BACKGROUND

The present disclosure relates to a substrate processing apparatus, and more particularly, to a substrate processing apparatus that is configured to prevent wobbling of a rotational shaft when the rotational shaft supporting a substrate seating portion rotates.

Generally, in order to manufacture a semiconductor device, a display device, and a thin film solar cell, a thin film deposition process for depositing a thin film of a specific material on a substrate, a photolithography process for exposing or masking a selected region of the thin film using a photoresist material, an etching process for patterning the thin film by removing the selected or unselected region are performed. The thin film deposition process and the etching process are preformed in a substrate processing apparatus that is optimized by being vacuumed.

However, as a size of the substrate increases recently, it becomes difficult to uniformly inject process gas on a surface of the substrate. Therefore, there is a problem that the uniformity of the film formed on the semiconductor device is deteriorated. According to the related art, to solve this problem, the thin film has been deposited on the semiconductor substrate while rotating the semiconductor substrate, thereby improving the uniformity of a thickness of the thin film.

At this point, the rotation of the substrate is performed by disposing the substrate on a substrate seating portion and connecting the substrate seating portion to a rotational shaft. In addition, the rotational shaft rotates by rotational force applied from an external driving motor.

An O-ring is used for a connecting portion between the rotational shaft and the driving motor. However, the O-ring is quickly worn as it is used for a long time and quickly deteriorated when it is exposed to a high temperature. Accordingly, there is a problem that the O-ring may be damaged when the heat generated by the substrate seating portion is transferred to the O-ring through the rotational shaft. When the O-ring is damaged, the substrate seating portion does not rotate horizontally but rotates in a wobbling state. This causes the uniformity of the thickness of the thin film deposited on the substrate to be deteriorated.

### SUMMARY

The present disclosure provides a substrate processing apparatus that enhances coupling force between a rotational shaft and a shaft by inserting an auxiliary member between the rotational shaft and the shaft when the rotational shaft that supports, rotates, and moves up and down a substrate seating portion is inserted into the shaft and connected to a central shaft.

The present disclosure also provides a substrate processing apparatus that enhances coupling force between a rotational shaft and a shaft by forming a dent portion on a lower portion of the rotational shaft and forming a coupling portion inserted in the dent portion on an auxiliary member.

The present disclosure also provides a substrate processing apparatus that improves uniformity of a thin film deposited on a substrate by preventing wobbling (i.e., precession motion) of the rotational shaft by employing a coupling unit that is different in a structure from an O-ring that has been used in the related art.

The present disclosure also provides a substrate processing apparatus that improves uniformity of a thin film deposited on a substrate by preventing wobbling (i.e., precession motion) of the rotational shaft by installing an alignment cap for maintaining center on a rotational shaft.

In accordance with an exemplary embodiment, a substrate processing apparatus includes a chamber having a reaction space; a substrate seating portion located in the reaction space; and a rotational shaft portion including a rotational shaft connected to a lower central region of the substrate seating portion, a connecting member in which an end of the rotational shaft is fixedly inserted, and a contacting member making the rotational shaft and the connecting shaft tightly coupled to each other.

The contacting member may include a tube-shaped contacting body and an elastic portion provided in at least one of upper and lower regions of the contacting body. The rotational shaft may be formed of quartz, the connecting member may be formed of a SUS material and the contacting member may be formed of the same material as the connecting member.

The elastic portion may be formed by cutting at least one of the upper and lower regions of the contacting body lengthwise into a plurality of cutting sections and bending the cutting sections of the contacting body by at least once.

The contacting member may be located at the upper region of the connecting member and the rotational shaft portion may include an auxiliary member making the connecting member and the rotational shaft tightly coupled to each other at the lower region of the connecting member.

The contacting member may include a contacting body, a first elastic portion formed on an upper region of the contacting body and making the rotational shaft and the connecting member tightly coupled to each other at an upper region of the connecting member, and a second elastic portion formed on a lower region of the contacting body and making the rotational shaft and the connecting member tightly coupled to each other at a lower region of the connecting member.

The contacting member may include a first contacting member making the rotational shaft and the connecting member tightly coupled to each other at an upper region of the connecting member, and a second contacting member making the rotational shaft and the connecting member tightly coupled to each other at a lower region of the connecting member.

The rotational shaft portion may include a central body formed in a ring shape and a centering body having a cap inclination surface which is inclined downward and located on the central body, wherein a centering cap tightly contacted to the rotational shaft may be provided on the cap inclination surface.

The centering body may include at least one first centering body having a first cap inclination surface inclined from an outer side to an inner side and at least one second centering body having a second cap inclination surface inclined from an inner side to an outer side, wherein a shaft inclination surface corresponding to the cap inclination surface may be provided at an end of the rotational shaft.

The rotational shaft may include an upper supporting portion, a lower supporting portion under the upper supporting portion, and an inclined supporting portion between the upper and lower supporting portions, wherein the rotational shaft in a region of the inclined supporting portion may include an outer diameter that is gradually reduced from an upper portion to a lower portion.

The substrate processing apparatus may further include an auxiliary member disposed between the rotational shaft and the connecting member, wherein the auxiliary member may include an upper auxiliary portion contacted to the upper supporting portion, a lower auxiliary portion contacted to the lower supporting portion, an inclined auxiliary portion contacted to the inclined supporting portion, and a finishing auxiliary portion contacting a lower portion of the rotational shaft.

The rotational shaft may include a dent portion provided on a lower portion of the rotational shaft and the auxiliary member may include a coupling portion inserted and coupled into the dent portion.

At least one O-ring may be used as the contacting member or the contacting member may include a contacting body formed in a tube shape and an elastic portion provided on at least one of upper and lower portions of the contacting body, wherein, when the O-ring may be used as the contacting member, the O-rings may include a first O-ring disposed between the connecting member and the rotational shaft and a second O-ring disposed between the auxiliary member and the rotational shaft.

In accordance with another exemplary embodiment, a substrate processing apparatus includes a chamber having a reaction space; a substrate seating portion located in the reaction space; and a rotational shaft portion including a rotational shaft connected to a lower central region of the substrate seating portion, a connecting member in which an end of the rotational shaft is fixedly inserted, and a centering cap including a ring-shaped central body and a centering body located on the central body and having a cap inclination surface inclined downward, wherein the rotational shaft close-contacting the cap inclination surface.

The centering body may include a sidewall surface extending from an outer surface of the central body and a cap inclination surface that is inclined downward from an end of the sidewall surface toward the upper surface of the central body; a shaft inclination surface corresponding to the cap inclination surface may be provided at an end of the rotational shaft; the rotational shaft may be formed of quartz; and the connecting member may be formed of a SUS material.

The substrate processing apparatus may further include a contacting member making the connecting member tightly coupled to the rotational shaft, wherein an O-ring may be used as the contacting member or the contacting member may include a tube-shaped contacting body and an elastic portion provided on at least one of upper and lower portions of the contacting body.

The elastic portion may be formed by cutting at least one of the upper and lower portions of the contacting body lengthwise into a plurality of cutting sections and bending the cutting sections of the contacting body by at least once.

In accordance with still another exemplary embodiment, a substrate processing apparatus includes a substrate seating portion located in the reaction space; and a rotational shaft portion including a rotational shaft connected to a lower central region of the substrate seating portion, a connecting member in which an end of the rotational shaft is fixedly inserted, a contacting member making the rotational shaft and the connecting shaft tightly coupled to each other, and an auxiliary member disposed between the rotational shaft and the connecting member, wherein the rotational shaft includes an upper supporting portion adjacent to an upper side of the connecting member, a lower supporting portion under the upper supporting portion, and an inclined supporting portion between the upper and lower supporting portions, wherein the rotational shaft in a region of the inclined supporting portion has a diameter that is gradually reduced downward.

The auxiliary member may include an upper auxiliary portion contacted to the upper supporting portion, a lower auxiliary portion contacted to the lower supporting portion, an inclined auxiliary portion contacted to the inclined supporting portion, and a finishing auxiliary portion contacted to a lower portion of the rotational shaft.

The rotational shaft may include a dent portion provided on a lower portion of the rotational shaft and the auxiliary member may include a coupling portion inserted and coupled into the dent portion.

In accordance with still yet another exemplary embodiment, a substrate processing apparatus includes a substrate seating portion located in the reaction space; and a rotational shaft portion including a rotational shaft connected to a lower central region of the substrate seating portion, a connecting member in which an end of the rotational shaft is fixedly inserted, a contacting member making the rotational shaft and the connecting shaft tightly coupled to each other, the contacting member including a tube-shaped contacting body and an elastic portion provided on at least one of upper and lower portions of the contacting body.

The rotational shaft may be formed of quartz, the connecting member may be formed of a SUS material, and the contacting member may be formed of a same material as the connecting member, wherein the elastic portion may be formed by cutting at least one of the upper and lower regions of the contacting body lengthwise into a plurality of cutting sections and bending the cutting sections of the contacting body by at least ten times.

In accordance with still yet further another exemplary embodiment, a substrate processing apparatus includes a substrate seating portion located in the reaction space; and a rotational shaft portion including a rotational shaft connected to a lower central region of the substrate seating portion, a connecting member in which an end of the rotational shaft is fixedly inserted, and a centering cap including a ring-shaped central body and a centering body located on the central body and having a cap inclination surface inclined downward, wherein the rotational shaft close-contacting the cap inclination surface.

The substrate processing apparatus may further include a driving unit applying rotational force to the rotational shaft portion, wherein the rotational shaft may be formed of quartz, the connecting member may be formed of a SUS material, and a shaft inclination surface corresponding to the cap inclination surface may be provided at an end of the rotational shaft.

### BRIEF DESCRIPTION OF THE DRAWINGS

Exemplary embodiments can be understood in more detail from the following description taken in conjunction with the accompanying drawings, in which:

FIG. 1 is a schematic view of a substrate processing apparatus according to an exemplary embodiment;

FIG. 2 is a cross-sectional view of a bellows portion of the substrate processing apparatus of FIG. 1;

FIGS. 3 and 4 are partial perspective views of a rotational shaft of the substrate processing apparatus of FIG. 1;

FIG. 5 is a partly cut-away perspective view of an auxiliary member of the substrate processing apparatus of FIG. 1;

FIG. 6 is a partly cut-away perspective view of a shaft of the substrate processing apparatus of FIG. 1;

FIG. 7 is a perspective view of a finishing member of the substrate processing apparatus of FIG. 1;

FIGS. 8 and 9 are partial cross-sectional views of a modified example of the bellows portion of FIG. 2;

FIG. 10 is a cross-sectional view of a substrate processing apparatus according to another exemplary embodiment;

FIG. 11 is an exploded cross-sectional view of a rotational shaft portion of the substrate processing apparatus of FIG. 10;

FIG. 12 is a schematic exploded view of a rotational shaft portion of the substrate processing apparatus of FIG. 10;

FIG. 13 is a perspective view of the rotational shaft portion of FIG. 12;

FIGS. 14 and 15 are cross-sectional views of modified examples of the rotational shaft portion of FIGS. 11 and 12;

FIG. 16 is a cross-sectional view of a substrate processing apparatus according to still another embodiment;

FIG. 17 is a schematic exploded view of a rotational shaft portion of the substrate processing apparatus of FIG. 16;

FIG. 18 is an exploded perspective view of an alignment cap of the rotational shaft portion of FIG. 17;

FIG. 19 is a cross-sectional view of the rotational shaft portion of FIG. 17; and

FIGS. 20 and 21 are respectively exploded perspective and cross-sectional views of a modified example of the rotational shaft portion of FIGS. 17 and 19.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

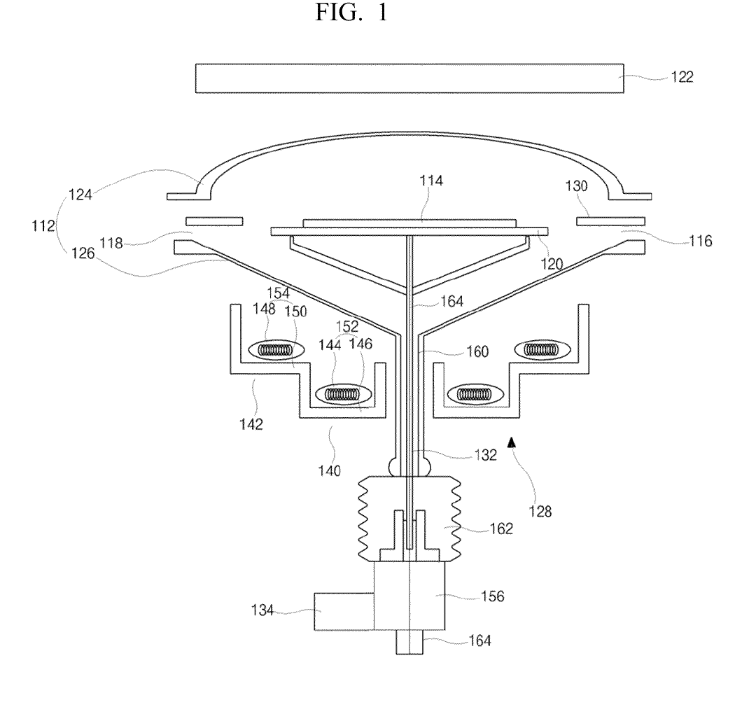

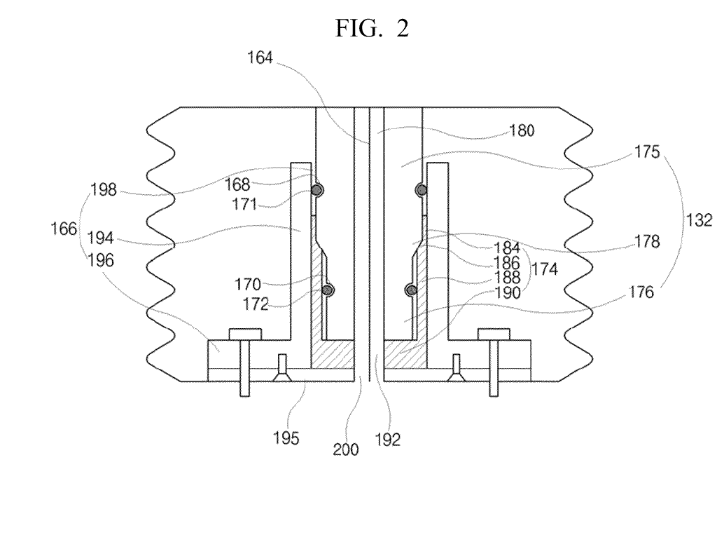

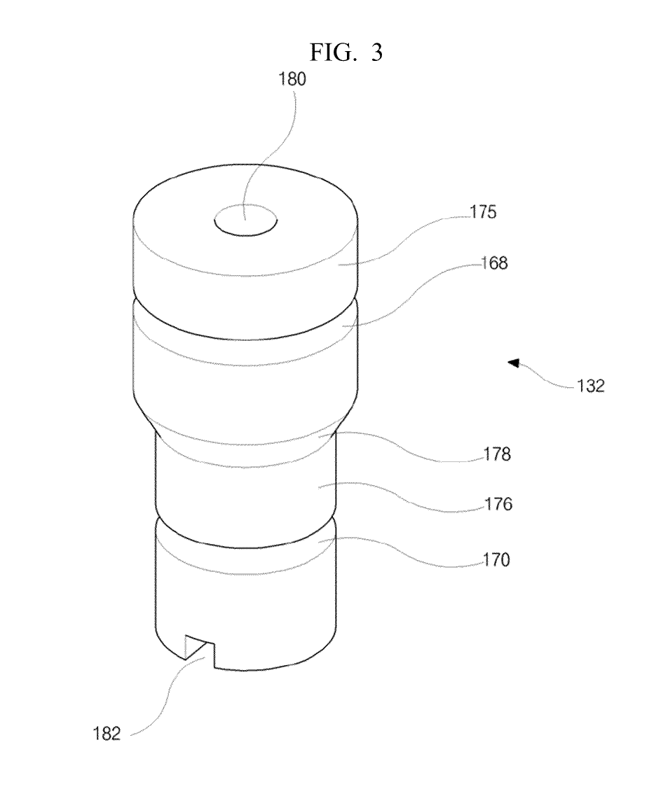

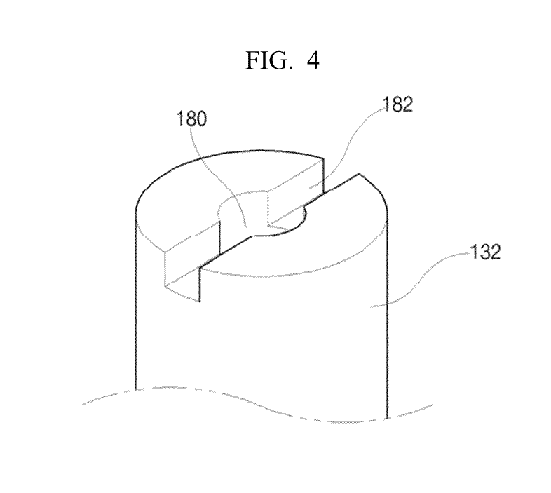

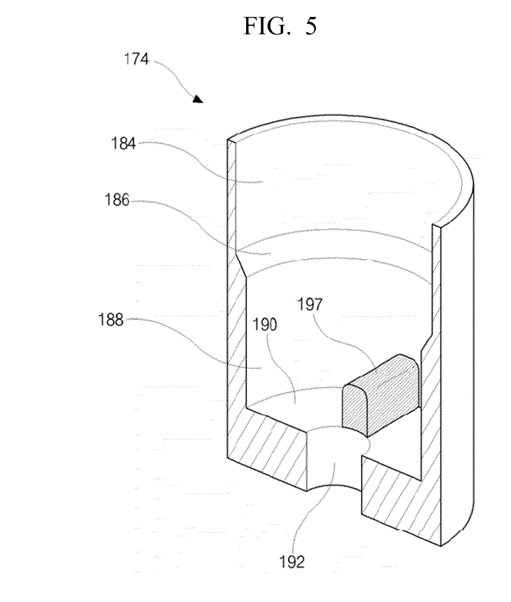

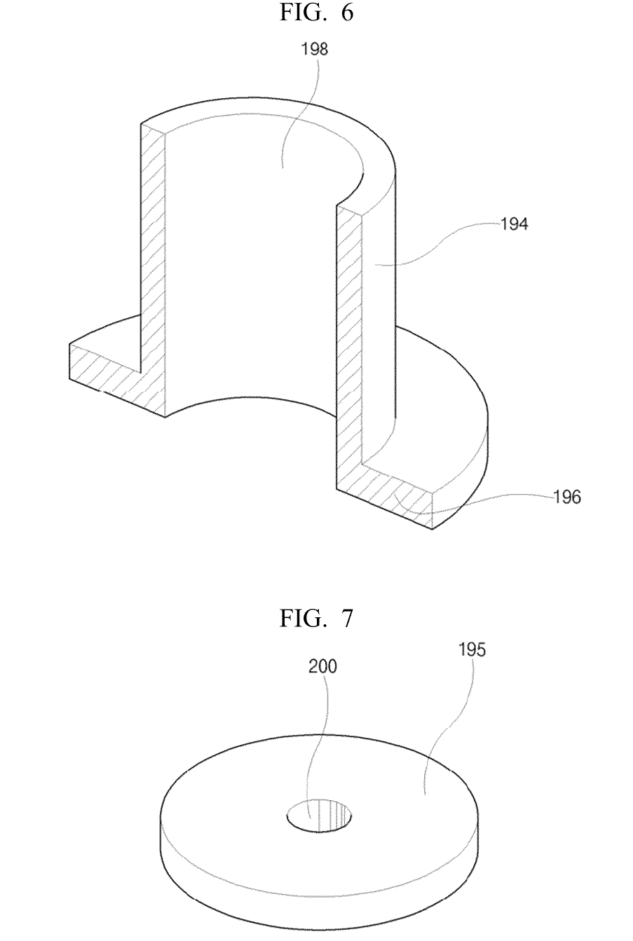

FIG. 1 is a schematic view of a substrate processing apparatus according to an exemplary embodiment, FIG. 2 is a cross-sectional view of a bellows portion of the substrate processing apparatus of FIG. 1, FIGS. 3 and 4 are partial perspective views of a rotational shaft of the substrate processing apparatus of FIG. 1, FIG. 5 is a partly cut-away perspective view of an auxiliary member of the substrate processing apparatus of FIG. 1, FIG. 6 is a partly cut-away perspective view of a shaft of the substrate processing apparatus of FIG. 1, and FIG. 7 is a perspective view of a finishing member of the substrate processing apparatus of FIG. 1.

Referring to FIG. 1, a substrate processing apparatus according to an exemplary embodiment includes a chamber 112, a gate valve 116, which is installed on a side surface of the chamber 112 and through which a substrate 114 goes in and out, an outlet 118 through which gas is discharged out of the chamber 112, a substrate seating portion 120 on which a substrate 114 is disposed, an edge ring 130 installed on an outer circumference of the substrate seating portion 120, and upper and lower heating units 122 and 128 that are respectively installed at upper and lower portions of the chamber 112 to heat the substrate 114.

In a lower dome 126, an inclined plane 158 is formed to extend from a periphery of the chamber 112 to a portion near a rotational shaft 132, and the lower heating unit 128 is installed divide a lower portion of the chamber 112 into an inner region 140 and an outer region 142. The lower heating unit 128 includes a first lower heating unit 152 installed in the inner region 140 and a second lower heating unit 154 installed in the outer region 142. The first lower heating unit 152 includes a plurality of first lamps 144 that are radially disposed in the inner region 140 about the rotational shaft 132 and a plurality of first reflective plates 146 that are installed under the first lamps 144 and on side surfaces of the first lamps 144. The second lower heating unit 154 includes a plurality of second lamps 148 that are radially disposed in the outer region 142 about the rotational shaft 132 and a plurality of second reflective plates 150 that are installed under the second lamps 146 and on side surfaces of the second lamps 146.

In the substrate processing apparatus, a driving unit 134 and a magnetic seal 156 are formed in addition to the rotational shaft 132. The rotational shaft 132 supports the substrate 114 and moves the substrate 114 up and down. The driving unit 134 is connected to the rotational shaft 132 to drive the rotational shaft 132, and the magnetic seal 156 airtightly seals the chamber 112 when the rotational shaft 132 rotates and moves up and down. The rotational shaft 132 includes a central supporting shaft supporting a center of the substrate seating portion 120 and a plurality of peripheral supporting shafts supporting a peripheral portion of the substrate seating portion 120.

The chamber 112 is divided into an upper region and a lower region coupled to the upper region. The upper and lower regions are defined by upper and lower domes 124 and 126, respectively. Each of the upper and lower domes 124 and 126 has a curved plane. The upper and lower heating units 122 and 128 are respectively installed at upper and lower portions of the chamber 112 so as to keep an internal temperature of the chamber 112 high. A belljar heater having an RF electrode (not shown) is used as the upper heating unit 122 and a lamp heater is used as the lower heating unit 128.

The lower dome 126 is provided with an inclined plane 158 defining a bottom surface of the chamber 112 and a through hole 160 through which the rotational shaft 132 passes. The rotational shaft 132 passing through the through hole 160 is connected to a central shaft (not shown) located on the magnetic seal 156. The central shaft is connected to the driving unit 134 to drive the rotational shaft 132. A bellows 162 is installed between a lower portion of the through hole 160 and the magnetic seal 156 to keep the airtightness of the chamber 112 when the rotational shaft 132 moves up and down.

A thermocouple 164 for measuring a temperature of the substrate seating portion 120 is built in the central hole 180 of the rotational shaft 132. The thermocouple 164 is connected to a terminal 164 located on a lower portion of the magnetic seal 156 to measure the temperature of the substrate seating portion 120 located in the chamber 112. Since the rotational shaft 132 is formed of quartz, it cannot be directed connected to the central shaft formed of metal such as stainless steel. Therefore, the rotational shaft 132 is fixed on a cylindrical shaft 166 formed of metal such as stainless steel by a connecting member and the shaft 166 is connected to the central shaft.

FIG. 2 is a cross-sectional view illustrating in detail the rotational shaft 132 inserted and coupled into the shaft 166 in the bellows 62. FIG. 3 is a perspective view illustrating the rotational shaft 132. FIG. 4 is a perspective view illustrating in detail the lower portion of the rotational shaft 132. FIG. 5 is a cut-away perspective view illustrating in detail an internal structure of an auxiliary member 174 and FIG. 6 is a cut-away perspective view illustrating in detail an internal structure of the shaft 166. FIG. 7 is a perspective view of the finishing member 915. The following will describe the rotation shaft 132 coupled to the shaft 166 in detail with reference to FIGS. 2 to 7.

Referring to FIG. 2, the thermocouple 164 is built in a first central hole 180 formed in a central portion of the rotational shaft 132 and upper and lower grooves 168 and 170 are respectively formed along outer circumferences of upper and lower portions of the rotational shaft 132 corresponding to the shaft 166. In order to maintain the airtight of the chamber 1112 when the rotational shaft 132 is coupled into the shaft 166, upper and lower O-rings 171 and 172 are inserted into the upper and lower grooves 168 and 170.

As illustrated in FIGS. 2 to 4, the supporting member 166 corresponding to the shaft 166 has a diameter that is gradually reduced as it goes from an upper portion to a lower portion. The rotational shaft 132 coupled to the shaft 166 and formed in a cylindrical shape has an upper supporting portion 175 having a first outer diameter, a lower supporting portion 176 having a second outer diameter less than the first outer diameter, and an inclined supporting portion 178 located between the upper and lower supporting portions 175 and 176 and having an inclined plane and an outer diameter that is gradually reduced downward. Like the inclined supporting portion 178, the lower supporting portion 176 may be designed such that a diameter thereof is gradually reduced downward.

As illustrated in FIGS. 2 and 6, the shaft 166 includes a cylindrical main body 194, a protruding portion 196 located on a lower portion of the main body 194 and coupled to the central shaft, and a cylindrical inner space 198 which is formed in the main body and in which the rotational shaft 132 is inserted.

The rotational shaft 132, upper and lower O-rings 171 and 172, and auxiliary member 174 are inserted in the inner space 198 of the shaft 166. In the shaft 166, the inner space 198 extends from an upper portion to a lower portion where the protruding portion 196 is located. The diameter of the inner space 198 is uniform. In order to increase an area of the inner space 198, the inner spacer 198 may be formed such that the inner diameter thereof gradually increased downward to form inclination.

As illustrated in FIG. 2, the upper portion of the rotational shaft 132 is coupled to the shaft 166 with the upper O-ring 171 interposed therebetween. A portion of the rotational shaft 132, which is lowered from the upper O-ring 171 by 1 cm to 3 cm is coupled to the shaft 166 with the auxiliary member 174 and the lower O-ring 172 interposed therebetween. The auxiliary member 174 inserted in a space defined between the shaft 166 and the rotational shaft 132 includes an upper auxiliary portion 184 corresponding to the upper supporting portion 175, an inclined auxiliary portion 186 corresponding to the inclined supporting portion 178, a lower auxiliary portion 188 corresponding to the lower supporting portion 176, and a finishing auxiliary portion 190 contacting an undersurface of the rotational shaft 132 and provided with a second central hole 192 through which the thermocouple 164 passes. The auxiliary member 174 is formed of Teflon.

The lower O-ring 172 is interposed between the lower auxiliary portion 188 of the auxiliary member 174 and the lower supporting portion 176 of the rotational shaft 132. In addition, the lower portion of the shaft 166 is coupled to a disc-shaped finishing member 185 so that it is coupled to the protruding portion 196 and shields the auxiliary member 174. A third central hole 200 is formed through a central portion of the finishing member 185. The thermocouple 164 passes through the third central hole 200. The finishing member 195 is formed of stainless steel.

The rotational shaft 132 is assembled with the shaft 166 according to the following process. In the first step, the upper and lower O-rings 171 and 172 are respectively installed in the upper and lower grooves 168 and 170 formed along the outer circumferences of the upper and lower supporting portions 175 and 176. In the second step, the rotational shaft 132 is inserted into the auxiliary member 174. In the rotational shaft 132 and the auxiliary member 174, although the upper supporting portion 175 closely contacts the upper auxiliary portion 184 of the auxiliary member 174, the lower supporting portion 176 and the lower auxiliary portion 188 do not closely contact the lower O-ring 172. The finishing auxiliary portion 190 closely contacts the lower portion of the rotational shaft 132.

In the third step, the rotational shaft 132 on which the auxiliary member 174 and the upper and lower O-rings 171 and 172 are installed is inserted into the inner space 198 of the shaft 166. The auxiliary member 174 passing through the inner space 198 is in-plane with an undersurface of the shaft 166. The upper supporting portion 175 and the shaft 166 are coupled to each other with the upper O-ring 171 interposed therebetween. In the inner space 198, the upper O-ring 171 is spaced apart from the upper auxiliary portion 184 by 1 to 3 cm. When the process is performed in the chamber 112, high temperature inner gas is transferred into the bellows 162 and thus the auxiliary member 174 formed of Teflon is not exposed to the inner gas.

Referring to FIG. 2, the auxiliary member 174 is located between the shaft 166 and the rotational shaft 132 and is not directly exposed to the inner gas. However, a temperature of the upper O-ring 171 that is not directly exposed to the inner gas increases. Accordingly, in order not for the upper auxiliary portion 184 to be affected by the high temperature inner gas, the upper auxiliary portion 184 is spaced apart from the upper O-ring 171 by 1 to 3 cm. In the fourth step, the protruding portion 196 of the shaft 166 is coupled to the finishing member 195 using a bolt. In the fifth step, the protruding portion 196 of the shaft 166 is coupled to a lower central shaft (not shown).

As described above, as the shaft 166 and the rotational shaft 132 contact the upper and lower O-rings 171 and 172 with the auxiliary member 174 is interposed therebetween, and the contacting surface between the shaft 166 and the auxiliary member 174 and the contacting surface between the rotational shaft 132 and the auxiliary member 174 are enlarged, the frictional force resisting against the rotational force when the rotational shaft 132 rotates increases. As a result, the shaft 166 and the rotational shaft 132 can be more securely coupled to each other. In addition, at the lower supporting portion 176 of the rotational shaft 132, the shaft 166 closely contacts the lower auxiliary portion 188 of the auxiliary member 174 but the lower auxiliary portion 188 does not closely contact the lower supporting portion 176 due to the lower O-ring 172. Accordingly, in order to improve the contact property between the rotational shaft 132 and the auxiliary member 174, a width of one of the lower supporting portion 176 and the lower auxiliary portion 188 is reduced. Alternatively, the rotational shaft 132 may be designed to have a plurality of steps whose diameters are gradually reduced downward, and the auxiliary member 174 is designed to correspond to this rotational shaft 132.

As illustrated in FIGS. 3 to 5, in order to improve the contact property between the rotational shaft 132 and the auxiliary member 174, a dent portion 182 is formed on the lower portion of the rotational shaft 132 and a coupling portion 197 that can be inserted and coupled into the dent portion 182 is formed on the finishing auxiliary portion 190 of the auxiliary member 174. As illustrated in FIG. 4, the dent portion 182 is formed on a straight line shape passing the central portion of the rotational shaft 132. However, the dent portion 182 may be formed in a cross shape or the like. The coupling portion 197 inserted into the dent portion 182 is designed having a snap-fitting structure so that there is no gap between the dent portion 182 and the coupling portion 197.

As illustrated in FIGS. 2 and 6, the inner space 184 of the shaft 166 has an inner diameter that is uniform throughout its length. However, in order to increase a contact area between the auxiliary member 174 and a surface defining the inner space 184, the inner diameter of the inner space 184 may be gradually increased downward or provided with a plurality of steps whose inner diameters are gradually increased downward. The auxiliary member 174 also has an outer shape corresponding to a shape of the inner space 184 such that an outer diameter is gradually increased downward for close contact with the inner space 184.

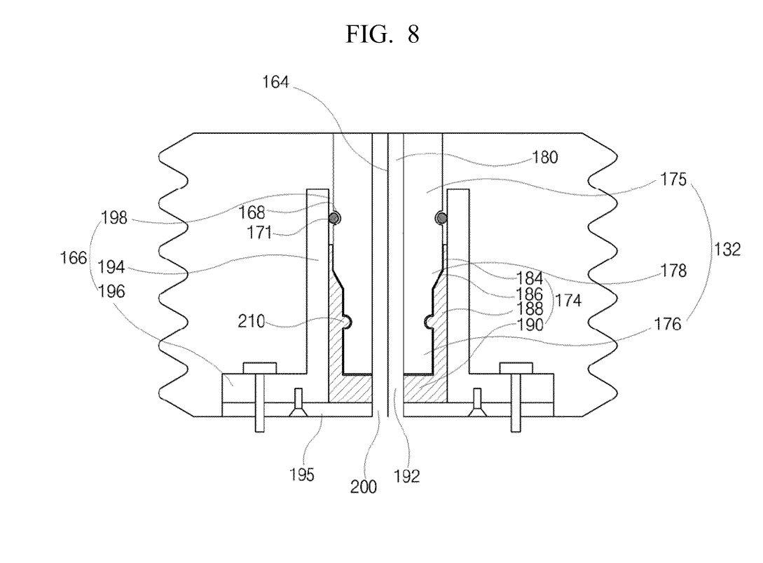

According to a modified example of the exemplary embodiment, as illustrated in FIG. 8, the upper O-ring 171 is inserted into the upper groove 168 and the upper portion of the rotational shaft 132 is coupled to the inner portion of the shaft 166. In addition, the auxiliary member 174 having a protrusion 210 protruding along an inner circumference of the lower auxiliary portion 188 is inserted into the lower groove 170 and the shaft 166 is coupled to the lower portion of the rotational shaft 132. As illustrated in FIG. 8, when the shaft 166 and the rotational shaft 132 are coupled to each other, no space exists between the rotational shaft 132 and the auxiliary member 174 by the lower O-ring 172. Therefore, the contact properties between the rotational shaft 132 and the auxiliary member 174 and between the auxiliary member 174 and the shaft 166 can be further enhanced.

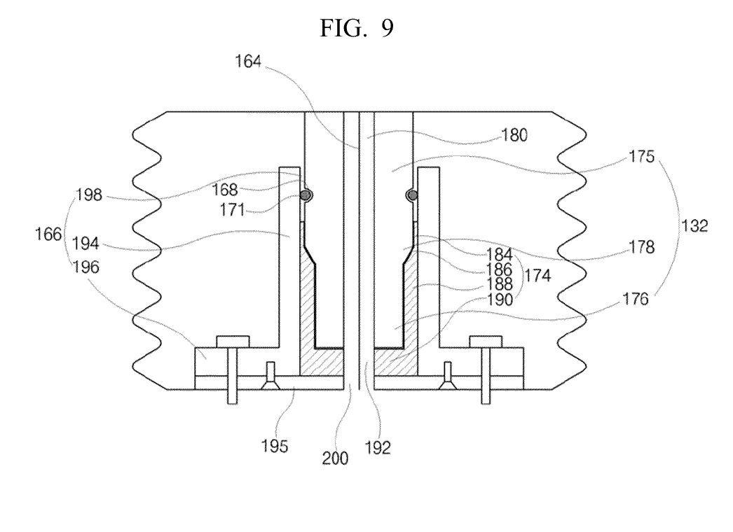

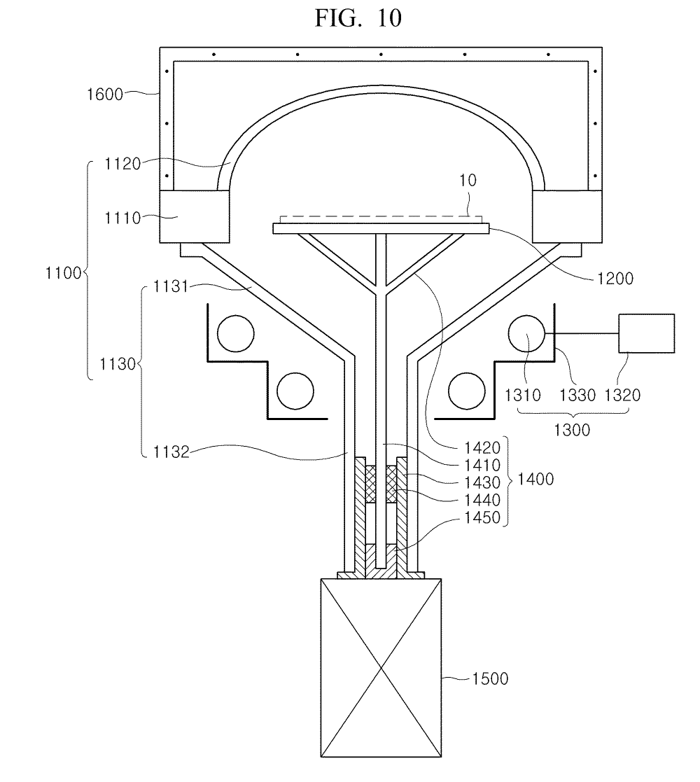

Furthermore, as illustrated in FIG. 9, the shaft 166 and the rotational shaft 132 may be coupled to each other with the auxiliary member 174 interposed therebetween without forming the lower groove on the rotational shaft 132 and the protrusion 210 on the auxiliary member 188. Even when the rotational shaft 132 is coupled to the shaft 166 as illustrated in FIG. 9, no gap between the auxiliary member 174 and the rotational shaft 132 is formed by the lower O-ring 172 as in FIG. 8. Therefore, the contact properties between the rotational shaft 132 and the auxiliary member 174 and between the auxiliary member 174 and the shaft 166 can be further enhanced.

The present invention is not limited to the above-described exemplary embodiment. The substrate processing apparatus may be variously modified. That is, a contacting member that improves the contact property between the shaft and the rotational shaft and is resistant to the high temperature may be provided. The following will describe a substrate processing apparatus including a lower structure having a rotational shaft portion including the contacting member. In the following description, the same parts as the foregoing embodiment will not be described. In addition, the features of the following exemplary embodiment may be applied to the foregoing exemplary embodiment. Needless to say, the features of the foregoing exemplary embodiment can be also applied to the following exemplary embodiment.

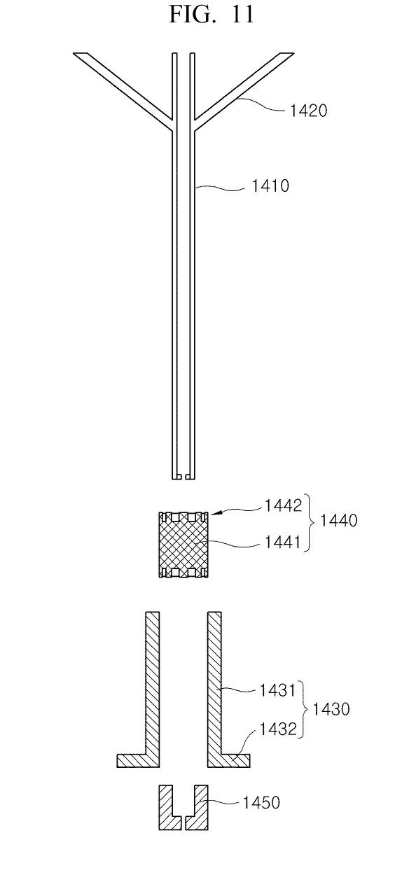

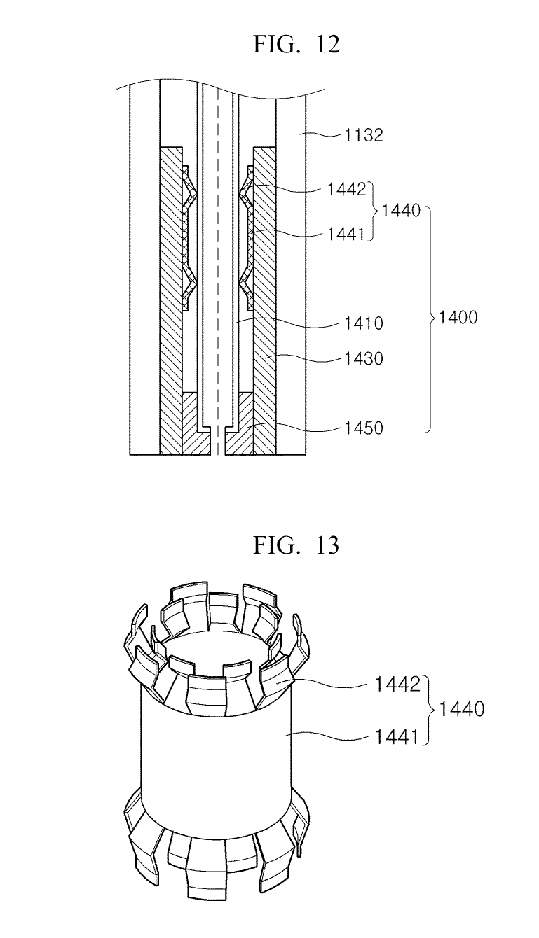

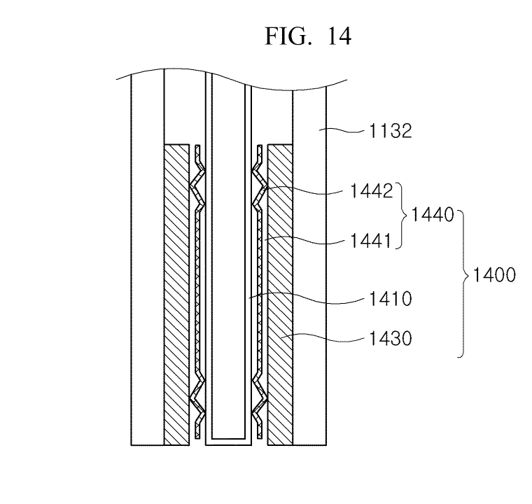

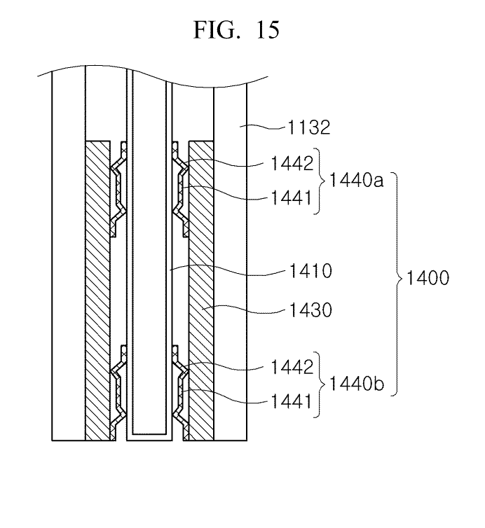

FIG. 10 is a cross-sectional view of a substrate processing apparatus according to another exemplary embodiment, FIG. 11 is an exploded cross-sectional view of a rotational shaft portion of the substrate processing apparatus of FIG. 10, FIG. 12 is a schematic exploded view of a rotational shaft portion of the substrate processing apparatus of FIG. 10, FIG. 13 is a perspective view of the rotational shaft portion of FIG. 12, and FIGS. 14 and 15 are cross-sectional views of modified examples of the rotational shaft portion of FIGS. 11 and 12.

Referring to FIGS. 10 to 13, a substrate processing apparatus of this exemplary embodiment includes a chamber 1100 having an internal reaction space, a substrate seating portion 1200 on which the substrate 110 is disposed in the chamber 1100, a lower heating unit 1300 that is located under the chamber 1100 to heat the reaction space, a rotational shaft portion 1400 coupled to the substrate seating portion 1200 and extends, and a driving unit 1500 applying rotational force to the rotational shaft portion 1400.

As illustrated in FIG. 10, the substrate processing apparatus may further include an upper heating unit 1600 that is located above the chamber 1100 to heat the reaction space. Although not shown in the drawings, a plasma generation unit generating plasma may be provided in the reaction space.

The chamber 1100 includes a chamber body 1110 defining the inner space and upper and lower domes 1120 and 1130.

The chamber body 1110 is formed in a cylindrical shape having opened top and bottom. However, the present invention is not limited to this. That is, the chamber body 1110 may be formed in a polygonal box shape. The chamber body 1110 may be formed of, at least partly, metal. In this exemplary embodiment, the chamber body 1110 is formed of aluminum or stainless steel. At this point, the chamber body 1110 functions as a sidewall defining the inner space of the chamber 1100. Although not shown in the drawings, the chamber body 1110 may be provided with a substrate inlet/outlet portion through which the substrate goes in and out of the chamber 1100 and a gas supply hole to which a gas supply unit for supplying reaction gas to the chamber is connected. Here, the substrate inlet/outlet portion may be the gate valve that is described in the foregoing exemplary embodiment.

The upper dome 1120 functions as an upper cover (i.e., a top wall of the chamber 1100) of the chamber body 1110. A lower region, i.e., a peripheral region of the dome is attached to a top wall of the chamber body 1110 to seal the upper region of the reaction space. At this point, it is effective that the upper dome 1120 may be detachably attached to the chamber body 1110.

The upper dome 1120 is formed of a high thermal conductive material so as to effectively transfer the heat generated by the upper heating unit 1600 to the reaction space. That is, the upper dome 1120 may be formed of a high light transmission plate (e.g., quartz) that can effectively transfer radiant heat to the reaction space. Therefore, the radiant heat conducted toward the upper dome 1120 in the reaction space of the chamber 1100 can pass through the upper dome 1120. The radiant heat passing through the upper dome 1120 is reflected by the upper heating unit 1600 and transferred to the reaction space through the upper dome 1120. However, the present invention is not limited to this. That is, the upper dome 1120 may be formed of a ceramic material.

The lower dome 1130 functions as a lower cover (i.e., a bottom wall of the chamber 1100) of the chamber body 1110. The lower dome 1130 is attached on the bottom wall of the chamber body 1110 to seal a lower region of the reaction space.

The lower dome 1130 is formed of a light transmission plate. Therefore, it is effective that the radiant heat generated by the lower heating unit 1300 located at an outer side of the chamber 1100 is transferred to the reaction space of the chamber 1100. In this exemplary embodiment, it is effective that the lower dome 1130 is formed of quartz. Accordingly, the lower dome 1130 functions as a window. Needless to say, it may be also possible that a portion of the lower dome 1130 is formed of the light transmission plate and the rest is formed of non-transmission plate that is excellent in the thermal conductivity.

As illustrated in FIG. 10, the lower dome 1130 includes an inclined bottom plate 1131 inclined downward and an extending pipe 1132 extending from a central portion of the bottom plate 1131 downward. The bottom plate 1131 is formed in an inverted cone shape having opened top and bottom.

As described above, the chamber 1100 is manufactured, which has a reaction space therein by assembling the chamber body 1110, upper dome 1120, and lower dome 1130. A pressure adjusting unit, a pressure measuring unit, and a variety of equipments for checking the inside of the chamber may be further installed. In addition, a view port through which a user can observe the inside of the chamber may be provided. A discharge unit for discharging impurities and unreacted materials out of the chamber may be further provided.

As illustrated in FIG. 10, the lower heating unit 1300 includes at least one lamp heater 1310, a power supply unit 1320 for supplying power to the lamp heater 1310, and a supporting unit 1330 for fixing the lamp heater 1310 on the lower region of the chamber 1100.

The lamp heater 1310 may be provided in the form of a bulb or a circular band. In this exemplary embodiment, a plurality of lamp heaters 1310 are disposed at central and peripheral regions. At this point, as illustrated in FIG. 10, the lamp heaters 1310 are disposed at the central region may be arranged at a lower region than the lamp heaters 1310 disposed at the peripheral region. To this end, the supporting unit 1330 may be formed having a step. The power of the power supply unit 1320 is supplied to the lamp heaters 1310 through the supporting unit 1330. Accordingly, it is effective that a socket to which the lamp heater 1310 is coupled is provided at a side of the supporting unit 1330. In addition, the supporting unit 1330 may function as the above-described reflective plate. To this end, it is effective that a reflective material may be coated on the supporting unit 1330 or the supporting unit 1330 is formed of a material that is excellent in the reflectance.

As described above, in this exemplary embodiment, the lamp heater 1310 is disposed under the lower dome 1130 formed of quartz. Therefore, the radiant heat of the lamp heater 1310 is transferred to the reaction space of the chamber 1100 through the lower dome 1130. At this point, only a portion of the lower dome 1130, which is adjacent to the lamp heater 1310 may be formed of quartz.

In this exemplary embodiment, the upper heating unit 1600 is disposed at the upper region of the chamber. Therefore, the inner space of the chamber 110 can be uniformly heated by the upper heating unit 1600. In addition, the heat loss through the upper portion of the chamber 1100 can be prevented. In addition, the upper heating unit 1600 may be disposed on the substrate 110 to directly supply heat energy to the substrate 110. Accordingly, by using the upper heating unit 1600 having an electric heat source, heat whose temperature does not suddenly change can be supplied to the substrate 110 and thus the damage of the substrate 110, which may be caused by the sudden temperature change, can be prevented.

The upper heating unit 1600 is formed in a cup shape covering the upper dome 1120 of the chamber 1100. A reflective coating may be formed on an inner surface of the upper heating unit 1600 so that the radiant energy loss by the lower heating unit 1300 can be reduced.

In addition, although not shown in the drawings, the upper heating unit 1600 may be formed by stacking a plurality of plates. At this point, thermal insulation materials may be disposed between the plates or cooling passages may be formed between the plates. A separated protective plate for protecting the chamber 1100 from external impact may be further provided.

As described above, the inner space of the chamber 1100 can maintain the process temperature by the lower heating unit 1300 under the chamber 110 and the upper heating unit 1600 above the chamber 1100.

In addition, the substrate seating portion 1200 for supporting the substrate 110 is provided in the inner space of the chamber 1100.

The substrate seating portion 1200 includes a susceptor. At this point, it is effective that the susceptor is formed in a plate shape that is almost same as the substrate 110. It is also effective that the substrate seating portion 1200 is formed of a material that is excellent in the thermal conductivity. The substrate seating portion 1200 has at least one substrate seating region so that at least one substrate 110 can be disposed on the substrate seating portion 1200.

In this exemplary embodiment, a rotational shaft portion 1400 that supports and rotates the substrate seating portion 120 in the reaction space of the chamber 1100 is provided.

As illustrated in FIGS. 11 and 12, the rotational shaft portion 1400 includes a rotational shaft 1410 coupled to a lower central region of the substrate seating portion 1200, a plurality of supporting shafts 1410 that extend to a periphery region of the substrate seating portion 120 at an upper portion of the rotational shaft 1410 to support the periphery portion of the substrate seating portion 1200, a shaft 1430 in which an end of the rotational shaft 1410 is fixedly inserted, a contacting member 1440 making the rotational shaft 1410 and the shaft 1430 closely contacting each other, and an auxiliary member 1450 that is provided at a lower portion of the shaft to support the rotational shaft 1410.

In this exemplary embodiment, the rotational shaft 1410 is provided in the form of hollow tube and formed of quartz.

In order to deposit a thin film on the substrate using the substrate processing apparatus of this exemplary embodiment, the inside environment of the chamber must be clean. That is, when there are impurities on the surface of the substrate, a defective thin film is deposited on the substrate. Particularly, even particles may cause the defect of the thin film in an epitaxial process. Therefore, the rotational shaft 1410 is formed of the quartz to minimize the generation of the particles in the chamber 1100. In addition, a wire that will be connected to a sensor for measuring a process condition of the chamber passes through an inside of the rotational shaft 1410. Therefore, the rotational shaft is provided in the form of the hollow tube.

An end of the rotational shaft 1410 is fixed on the lower central region of the substrate seating portion 1200. The supporting shafts 1420 extend from the upper region of the rotational shaft 1410 to the periphery region of the substrate seating portion 1200 and are coupled to the periphery region of the substrate seating portion 1200 so that the substrate seating portion 1200 can be located in the reaction space by the rotational shaft 1410 and the supporting shafts 1420.

Here, in order to minimize the affection of the heat, the rotational shaft 1410 extends to the lower region of the chamber 1100 lengthwise. That is, as illustrated in FIG. 10, the rotational shaft 1410 extends into an extending tube 1132 of the lower dome 1130 lengthwise. Therefore, at least a portion of the rotational shaft 1410 can be supported by the lower dome of the chamber 1100. If the rotational shaft 1410 is fixedly supported in the extending tube 1132, there may be a problem that the rotational shaft 1410 rotates in a state where it is one-sided or inclined

In addition, in order to apply the rotational force to the rotational shaft 1410 formed of the quartz, the rotational shaft 1410 must be fixedly coupled to the driving unit 1500. However, there is a problem that it is difficult to fixedly couple the rotational shaft 1410 formed of the quartz to the driving unit 1500.

That is, since the quartz has a property that it is easily broken by external impact, it is difficult to fix the rotational shaft 1410 formed of the quartz on the lower end of the chamber 1100.

Therefore, in this exemplary embodiment, the shaft 1430 is interposed between the rotational shaft 1410 and the extending tube 1132 of the lower dome 1130 to fix the rotational shaft 1410 and the shaft 1430 is fixed to the driving unit 1500 to transfer the rotational force of the driving unit to the rotational shaft 1410. In addition, since the shaft 1430 is supported by a lower portion of the extending tube 1132, the rotation of the rotational shaft 1410 inclined can be primarily prevented.

At this point, in order to minimize the generation of the particles, suppress the affection by the heat, and improve the coupling property, the shaft 1430 may be formed of a SUS material.

The shaft 1430 includes a shaft body 1431 formed in a tube shape having opened top and bottom and at least one fixing protrusion 1432 for fixing the shaft body 1431 to the driving unit 1500. The rotational shaft 1410 is fixedly inserted into the shaft body 1431. Further, the fixing protrusion 1431 extends from a lower end outer surface of the shaft body 1431 outward. Needless to say, the present invention is not limited to this. The fixing protrusion 1432 may be provided in the form of a band. In addition, it is effective that the fixing protrusion 1432 is fixed to the driving unit 1500 by a fixing unit such as a bolt, nut, screw, and the like. To this end, the fixing protrusion 1432 may be provided with a groove.

In this exemplary embodiment, instead of the O-ring that is used in the related art, the contacting member 1440 is used for the close tight coupling between the shaft 1430 and the rotational shaft 1410. The contacting member 1440 is formed of a same material as the shaft 1430. That is, the contacting member 1440 may be formed of the SUS material.

Here, as illustrated in FIGS. 10 and 12, the contacting member 1440 is located at the upper region of the shaft 1430. That is, the rotational shaft 1410 closely contacts the shaft 1430 at the upper portion of the shaft 1430. At this point, the auxiliary member 1450 is provided at the lower region of the shaft 1430. At this point, the auxiliary member 1450 may be formed of Teflon. In addition, an end of the auxiliary member 1450 extends to a region between the shaft 1430 and the rotational shaft 1410 to make the shaft 1430 close-contact the rotational shaft 1410 so that the wobbling and inclination of the rotational shaft 1410 can be further prevented by the auxiliary member 1450.

As illustrated in FIGS. 11 to 13, the contacting member 1440 includes a contacting body formed in a tube shape having opened top and bottom and an elastic portion 1442 that is formed by cutting at least one of upper and lower portions of the contacting body 1441 into a plurality of sections and bending the sections of the contacting body 1441 by 19 times.

The rotational shaft 1410 penetrates the contacting body 1441 formed in the tube shape. In this exemplary embodiment, the contacting body 1441 is formed of the SUS material to improve the assembling property, prevent the pollution, and reduce the manufacturing cost.

As illustrated in FIG. 13, the elastic portion 1442 is formed on each of the upper and lower regions of the contacting body 1441. Needless to say, the present invention is not limited to this. The elastic portion 1442 may be formed one of the upper and lower regions.

The elastic portion 1442 is formed by cutting each of the upper and lower regions of the contacting body 1441 lengthwise into a plurality of sections and bending the cut regions. At this point, it is effective that the bending directions of the adjacent cutting regions are different from each other. That is, if one cutting region is bent toward the central portion (i.e., toward the rotational shaft 1410) of the contacting body 1441, the adjacent cutting region is bent away from the contacting body 1441 (i.e., toward the shaft 1430. However, the present invention is not limited to this. The bending directions of the cutting regions may be same as each other. In addition, the number of the bending of the cutting regions may be more than 10 times.

At this point, it is effective that a vertical length of the cutting region is less than ¼ of a vertical length of the contacting body 1441. It is more effective that the vertical length of the cutting region may be within a range of 1/10 to ¼ of the vertical direction of the contacting body 1441. At this point, when the vertical length of the cutting region is less than 1/10 of the contacting body 1441, the bending area is reduced and thus the contacting body 1441 cannot effectively support the rotational shaft 1410 and the shaft 1430. In addition, when the vertical length of the cutting region is greater than ⅓ of the contacting body 1441, since the area of the contacting body 1441 is reduced, sufficient force cannot be applied to the elastic portion 1442.

As described above, the elastic portion 1442 has elastic force by bending the cutting regions of the contacting body 1441. Therefore, the elastic force of the elastic portion 1442 can fix the rotational shaft 1410 to the shaft 1430. In addition, since the elastic portion 1442 disposed between the rotational shaft 1410 and the shaft 1430 pushes the rotational shaft 1410 and the shaft 1430 with equal forces, the inclination of the rotational shaft 1410 can be prevented. Accordingly, the wobbling of the substrate seating portion 1200, which is caused by the inclination of the rotational shaft 1410 can be prevented.

Furthermore, as described previously, in this exemplary embodiment, the contacting member 1440 having the elastic portion 1442 and the contacting body 1441 is formed of the same material as the shaft 1430. Therefore, it can be prevented that the contacting member 1440 is easily deteriorated by heat and thus the service life of the contacting member 1440 becomes longer compared with the O-ring used in the related art. As a result, the reliability of the apparatus can be improved.

In a case of the O-ring used in the related art, it may be adhered to the shaft 1430 or the rotational shaft 1310 when it is used for a long time. Therefore, it is difficult to remove the O-ring for the maintenance. Due to this, the shaft is fully replaced and thus the maintenance cost and time increase. However, when the contacting member 1440 formed of the SUS material and having the elastic portion 1442 is used as in this exemplary embodiment, the contacting member 1440 can be easily attached and detached and thus the maintenance cost and time can be reduced.

At this point, the structure of the contacting member 1440 is not limited to this exemplary embodiment but can be variously modified.

As illustrated in a modified example of FIG. 14, the contacting member 1440 may be disposed in the whole space between the shaft 1430 and the rotational shaft 1410.

At this point, the elastic portion 1442 is formed on both of the upper and lower regions of the contacting member 1440. Therefore, the upper region of the shaft 1430 closely contacts the rotational shaft 1410 by the elastic portion 1442 formed on the upper region of the contacting member 1440 and the lower region of the shaft 1430 closely contacts the rotational shaft 1410 by the elastic portion 1442 formed on the lower region of the contacting member 1440. At this point, as illustrated in FIG. 14, the elastic portion 1442 may have a plurality of bending regions. As described above, the upper and lower regions, i.e., at least 11 regions, of the shaft 1430 closely contact the rotational shaft 1410 by one elastic member 1440 and thus the wobbling of the rotational shaft 1410 can be prevented. Here, it is effective that the length of the contacting member 1440 is equal to or slightly less than the length of the shaft 1430 by less than 10%. In addition, when the contacting member 1440 is disposed in the whole space between the shaft 1430 and the rotational shaft 1410 as described above, the auxiliary member 1450 that has been located at the lower portion of the shaft 1430 may be omitted.

In addition, as illustrated in a modified example of FIG. 15, first and second contacting members 1440a and 1440b may be located at the upper and lower regions of the shaft 1430, respectively. In this case, the upper and lower regions of the shaft 1430 can close contact the rotational shaft 1410 by the first and second contacting members 1440a and 1440b, respectively. The auxiliary member 1450 can be also omitted in this case. Each of the first and second contacting members 1440a and 1440b includes a contacting body 1441 and an elastic portion 1420 formed on each of upper and lower regions of the contacting body 1441. At this point, the pushing forces of the elastic portions 1420 formed on the upper and lower regions of the contacting body 1441 may be opposite to each other. That is, as illustrated in FIG. 15, the elastic portion 1442 formed on the upper portion of the contacting body 1441 has a bending region contacting the shaft 1430 and the elastic portion 1442 formed on the lower portion has a bending region contacting the rotational shaft 1410.

The modified examples may be at least partly applied to the previously described exemplary embodiments and to each other.

In this exemplary embodiment, the driving unit 1500 applies the rotational force to the rotational shaft 1410 that is coupled as described above. Although not shown in the drawings, the driving unit 1500 includes a motor generating the rotational force and a central shaft extending from the motor and connected to the rotational shaft 1410. At this point, the shaft 1430 that is previously described is connected to the central shaft. Therefore, the rotational force of the central shaft is transferred to the shaft 1430 and the rotational shaft 1410 rotates by the rotation of the shaft 1430. Accordingly, the substrate seating portion 1200 connected to the rotational shaft 1410 rotates. In addition, although not shown in the drawings, the driving unit further includes a housing enclosing the central shaft and a magnetic seal for sealing a gap between the central shaft and the housing. By this structure, the vacuum of the inner space of the chamber is not released by the driving unit 1500 provided at an outer side of the chamber. Needless to say, a sealing unit such as a bellows may be provided between the lower dome 1130 of the chamber 1100 and the housing.

The following will describe a substrate processing apparatus having a unit for preventing wobbling of the rotational shaft according to another exemplary embodiment. The same parts as the foregoing embodiment will not be described. In addition, the features of the following exemplary embodiment may be applied to the foregoing exemplary embodiments. Needless to say, the features of the foregoing exemplary embodiments can be also applied to the following exemplary embodiment.

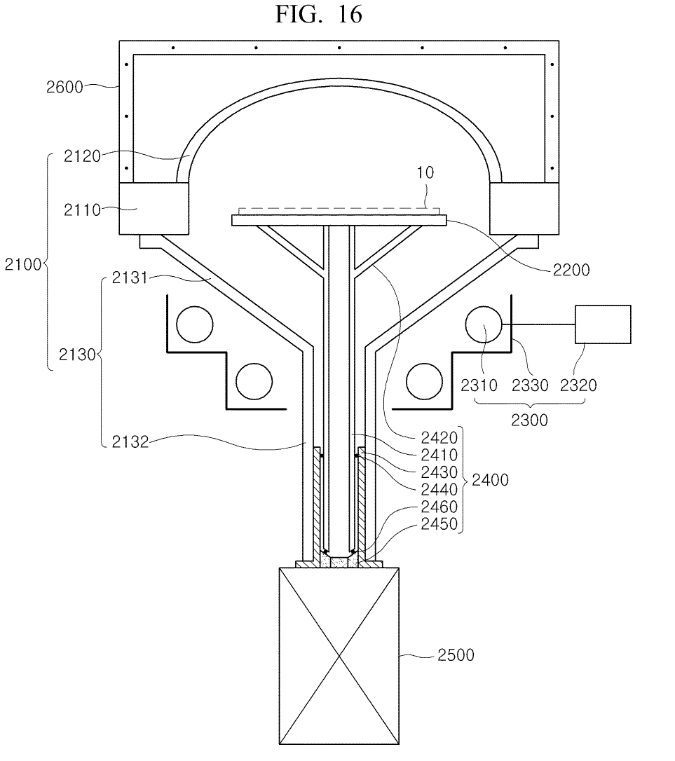

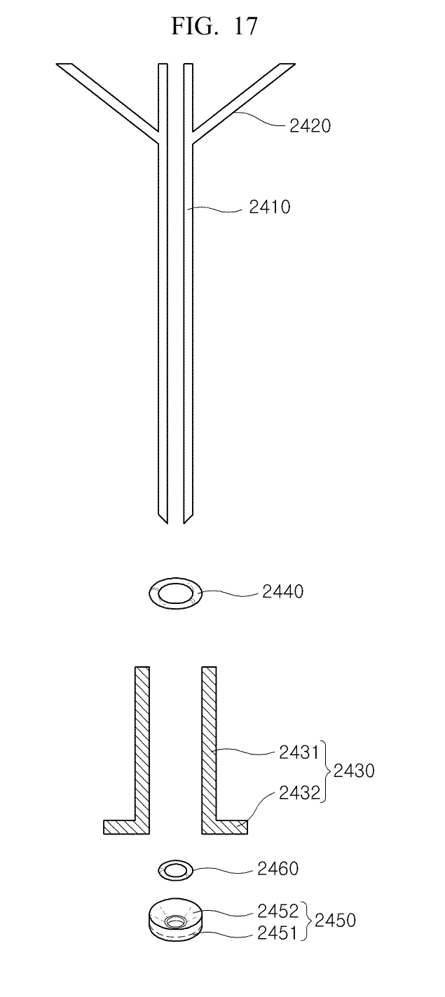

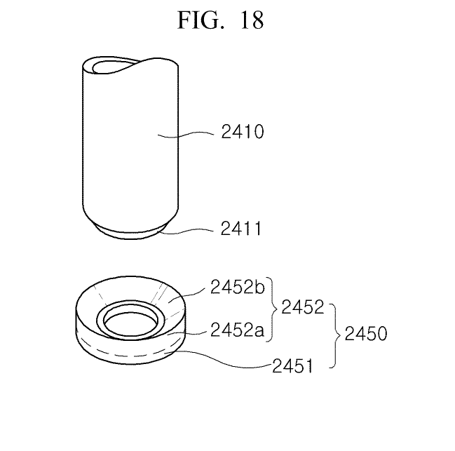

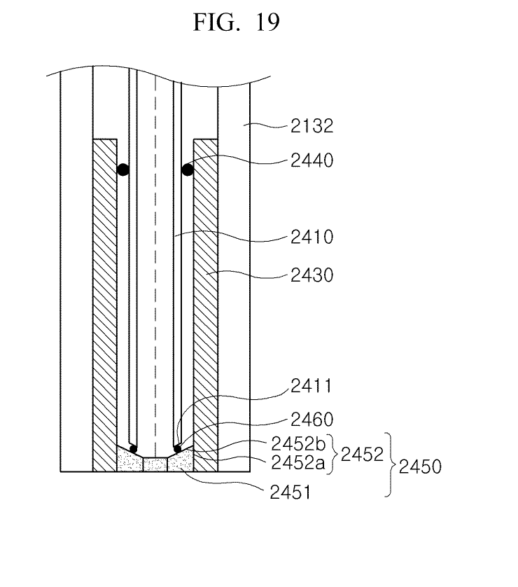

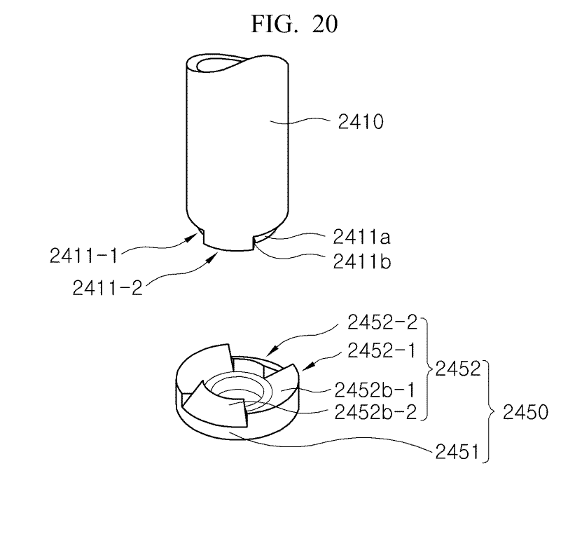

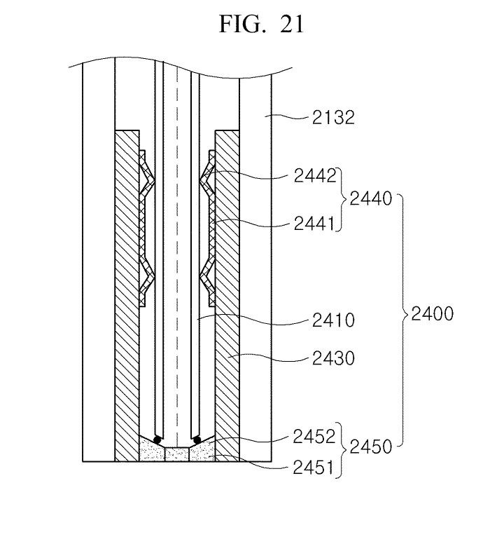

FIG. 16 is a cross-sectional view of a substrate processing apparatus according to still another embodiment, FIG. 17 is a schematic exploded view of a rotational shaft portion of the substrate processing apparatus of FIG. 16, FIG. 18 is an exploded perspective view of an alignment cap of the rotational shaft portion of FIG. 17, FIG. 19 is a cross-sectional view of the rotational shaft portion of FIG. 17, and FIGS. 20 and 21 are respectively exploded perspective and cross-sectional views of a modified example of the rotational shaft portion of FIGS. 17 and 19.

As illustrated in FIGS. 16 to 19, a substrate processing apparatus of this exemplary embodiment includes a chamber 2100 having an inner reaction space, a substrate seating portion 2200 on which a substrate 210 is disposed in the chamber 2100, a lower heating unit 2300 disposed under the chamber to heat the inner reaction space, a rotational shaft portion 2400 that extends and is connected to the substrate seating portion 2200, and a driving unit 2500 applying rotational force to the rotational shaft portion 2400.

The rotational shaft portion 2400 of this exemplary embodiment includes a rotational shaft connected to a lower central region of the substrate seating portion 220, a plurality of supporting shafts 2420 extending from an upper portion of the rotational shaft 2410 to a periphery region of the substrate seating portion 2200 to support the periphery region of the substrate seating portion 2200, a shaft 2430 in which an end of the rotational shaft 2410 is fixedly inserted, a contacting member 2440 for close contacting between the rotational shaft 2410 and the shaft 2430, and a centering cap 2450 disposed at a lower portion of the shaft 2430 to align the centering of the rotational shaft 2410. In addition, as illustrated in FIGS. 16 and 17, the substrate processing apparatus further includes a sealing member such as an O-ring 2460 disposed between the centering cap 2450 and the rotational shaft 2410.

In this exemplary embodiment, the shaft 2430 is inserted between the rotational shaft 2410 and an extending tube 2132 of a lower dome 2130 to fix the rotational shaft 2410. The shaft 2430 is fixed to the driving unit 2500 so that the rotational force of the driving unit 2500 can be transferred to the rotational shaft 2410. In addition, the shaft 2430 is supported by a lower portion of the extending tube 2132 and thus it can be primarily prevented that the rotational shaft 2410 rotates in a state where it is inclined.

Here, in order to minimize the generation of the particles, suppress the affection by the heat, and improve the coupling property, the shaft 2430 may be formed of a SUS material.

The centering cap 2450 is disposed on a lower end of the shaft 2430 to maintain the centering of the rotation shaft 2410 rotating. As illustrated in FIGS. 17 to 19, the centering cap 2450 includes a central body 2451 formed in a ring shape and a centering body 2452 disposed on the central body 2451 and inclined inward and downward. Here, it is effective that the central body 2451 and the centering body 2452 are formed of a same material.

The central body 2451 is formed in a donut shape and has a diameter that may be substantially equal to an inner diameter of the shaft 2430 within the margin of error. At this point, as illustrated in FIG. 16, the central body 2451 may be fixed to a lower end opening region of the shaft 2430. At this point, the central body 2451 may be fixed to the shaft 2430 by a fixing unit such as a bolt. Needless to say, the central body 2451 may be fixed to the shaft 2430 by a snap fitting manner. At this point, the central body 2451 may be formed of a same material as the shaft 2430.

The centering body 2452 has a section that is shaped like a triangle substantially. That is, the centering body 2452 has a sidewall surface 2452a extending from an outer surface of the central body 2451 and a cap inclination surface 2452b that is inclined downward from an end of the sidewall surface 2452a toward the upper surface of the central body 2451. The centering body 2452 may further include a contacting surface (not shown) closely contacting the upper surface of the central body 2451 and interconnecting the sidewall surface 2452a and the cap inclination surface 2452b.

Here, an end of the rotational shaft 2410 is connected to the cap inclination surface 2452 of the centering body 2452. At this point, the end of the rotational shaft 2410 slides along the cap inclination surface 2452b and is then fixed to the central portion of the centering cap 2450. Accordingly, the change of the center of the rotational shaft 2410, which may be caused by external factors, can be prevented. That is, it can be prevented that the rotational shaft 2410 deviates from the center of the centering cap 245, i.e., from the central region of the shaft 2430.

As illustrated in the drawings, the rotational shaft 2410 is provided at an end portion thereof with a shaft inclination surface 2411 corresponding to the cap inclination surface 2452b. The shaft inclination surface 2411 is inclined downward from an outer surface of the rotational shaft 2410 formed in a tube shape to an inner surface of the rotational shaft 2410. Therefore, the shaft inclination surface 2411 of the end portion of the rotational shaft 2410 closely contacts the cap inclination surface 2452b. As a result, the supporting force of the rotational shaft 2410 is improved by the cap inclination surface 2452b and thus the wobbling of the rotational shaft 2410 can be prevented. Therefore, the substrate seating portion 2200 can rotate horizontally without precession motion.

Here, as illustrated in FIGS. 16 and 17, it is effective that the O-ring 2460 is disposed between the shaft inclination surface 2411 and the cap inclination surface 2452b to improve the contacting force between the surfaces 2411 and 2452b, apply elastic force to the surfaces 2411 and 2452b, and prevent the surfaces 2411 and 2452b from being worn.

The centering body 2452 of this exemplary embodiment may be variously structured to align the center of the rotational shaft 2410.

FIG. 20 shows a modified example of the centering body. Referring to FIG. 20, the centering body 2452 may include at least one first centering body 2452-1 having a first cap inclination surface 2452b-1 inclined from an outer side to an inner side and at least one second centering body 2452-2 having a second cap inclination surface 2452b-2 inclined from an outer side to an inner side. The rotational shaft 2310 is provided at an end thereof with at least one first inclined portion 2411-1 having a first shaft inclination surface 2411a corresponding to the first cap inclination surface 2452b-1 of the first centering body 2452-1 and at least one second inclined portion 2411-2 having a second shaft inclination surface 2411b corresponding to the second cap inclination surface 2452b-2 of the second centering body 2452-2.

The first and second centering bodies 2452-1 and 2452-2 and the first and second inclined portions 2411-1 and 2411-2 mesh with each other. Therefore, the centering body 2452 can securely support the lower end of the rotational shaft 2410 and the wobbling of the rotational shaft 2410 can be prevented.

In this exemplary embodiment, the contacting member 2440 is provided to make the shaft 2430 and the rotational shaft 2410 close-contact each other. At this point, the O-ring shown in FIG. 17 is used as the contacting member 2440. A variety of other members may be used as the contacting member 2440.

Here, the contacting member 2440 supports the rotational shaft 2410 at the upper region of the shaft 2430 and the centering cap 2450 supports the rotational shaft 2410 at the lower end of the shaft 2430. Therefore, the rotational shaft can be fixedly supported at the upper and lower regions of the shaft 2430. In this exemplary embodiment, the change of the centering alignment of the rotational shaft 2410 can be prevented by the centering cap 2450.

As illustrated in a modified example of FIG. 21, the contacting member 2440 may be formed in a cylindrical shape to be used instead of the O-ring. The contacting member 2440 is formed of a same material as the shaft to be resistant to the wear and heat. The cylindrical contacting member 2440 may be formed of a SUS material.

At this point, as illustrated in FIG. 21, the contacting member 2440 may include a contacting body 2441 formed in a tube shape having opened top and bottom and an elastic portion 2442 that is formed by cutting at least one of upper and lower portions of the contacting body 2441 into a plurality of sections and bending the sections of the contacting body 2441 by more than 16 times.

According to the exemplary embodiments, since the auxiliary member is inserted between the rotational shaft and the shaft that are interconnected, the coupling force between the rotational shaft and the shaft is enhanced and thus the wobbling of the rotational shaft rotation can be minimized. In addition, since the rotational shaft has a plurality of steps whose diameters are gradually reduced downward and the auxiliary members corresponding to the steps are provided, the coupling force between the rotational shaft and the shaft can be enhanced. Further, since the dent portion to which the coupling portion of the auxiliary member is coupled is formed on the lower portion of the rotational shaft, the coupling force between the rotational shaft and the shaft can be further enhanced.

Furthermore, since the rotational shaft is fixedly inserted into the shaft and the contacting member formed of the same material as the shaft and having elasticity is disposed between the rotational shaft and the shaft, the service life of the apparatus increases and the cost and time for maintenance/repair can be reduced. Also, since the wobbling (i.e., precession motion) of the rotational shaft can be prevented, the thin film can be deposited with a uniform thickness.

In addition, since the centering cap coupled to the shaft is installed on the lower end of the rotational shaft, the wobbling of the rotational shaft can be prevented and thus the precession motion of the substrate seating portion can be suppressed.

Although the substrate processing apparatus has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A substrate processing apparatus comprising:
a chamber having a reaction space;
a substrate seating portion located in the reaction space; and
a rotational shaft portion comprising a rotational shaft connected to a lower central region of the substrate seating portion, a connecting member in which an end of the rotational shaft is fixedly inserted, and a contacting member making the rotational shaft and the connecting shaft tightly coupled to each other.

2. The substrate processing apparatus of claim 1, wherein the contacting member comprises a tube-shaped contacting body and an elastic portion provided in at least one of upper and lower regions of the contacting body, the rotational shaft is formed of quartz, the connecting member is formed of a SUS material and the contacting member is formed of the same material as the connecting member.

3. The substrate processing apparatus of claim 2, wherein the elastic portion is formed by cutting at least one of the upper and lower regions of the contacting body lengthwise into a plurality of cutting sections and bending the cutting sections of the contacting body at least once.

4. The substrate processing apparatus of claim 1, wherein the contacting member is located at the upper region of the connecting member and the rotational shaft portion comprises an auxiliary member making the connecting member and the rotational shaft tightly coupled to each other at the lower region of the connecting member.

5. The substrate processing apparatus of claim 1, wherein the contacting member comprises:
a first elastic portion formed on an upper region of a contacting body and making the rotational shaft and the connecting member tightly coupled to each other at an upper region of the connecting member; and
a second elastic portion formed on a lower region of the contacting body and making the rotational shaft and the connecting member tightly coupled to each other at a lower region of the connecting member.

6. The substrate processing apparatus of claim 1, wherein the contacting member comprises:
a first contacting member making the rotational shaft and the connecting member tightly coupled to each other at an upper region of the connecting member; and
a second contacting member making the rotational shaft and the connecting member tightly coupled to each other at a lower region of the connecting member.

7. The substrate processing apparatus of claim 1, wherein the rotational shaft portion comprises:
a central body formed in a ring shape; and
a centering body having a cap inclination surface which is inclined downward and located on the central body,
wherein a centering cap tightly contacted with the rotational shaft is provided on the cap inclination surface.

8. The substrate processing apparatus of claim 7, wherein the centering body comprises:
at least one first centering body having a first cap inclination surface inclined from an outer side to an inner side; and
at least one second centering body having a second cap inclination surface inclined from an inner side to an outer side,
wherein a shaft inclination surface corresponding to the cap inclination surface is provided at an end of the rotational shaft.

9. The substrate processing apparatus of claim 1, wherein the rotational shaft comprises an upper supporting portion, a lower supporting portion under the upper supporting portion, and an inclined supporting portion between the upper and lower supporting portions,
wherein the rotational shaft in a region of the inclined supporting portion has an outer diameter that is gradually reduced from an upper portion to a lower portion.

10. The substrate processing apparatus of claim 9, further comprising an auxiliary member disposed between the rotational shaft and the connecting member,
wherein the auxiliary member comprises an upper auxiliary portion contacted to the upper supporting portion, a lower auxiliary portion contacted to the lower supporting portion, an inclined auxiliary portion contacted to the inclined supporting portion, and a finishing auxiliary portion contacted to a lower portion of the rotational shaft, and
the rotational shaft comprises a dent portion provided on a lower portion of the rotational shaft and the auxiliary member comprises a coupling portion inserted and coupled into the dent portion.

11. The substrate processing apparatus of claim 9, wherein at least one O-ring is used as the contacting member or the contacting member comprises a contacting body formed in a tube shape and an elastic portion provided on at least one of upper and lower portions of the contacting body, and wherein, when the O-ring is used as the contacting member, the O-rings comprise a first O-ring disposed between the connecting member and the rotational shaft and a second O-ring disposed between the auxiliary member and the rotational shaft.

12. A substrate processing apparatus comprises:
a chamber having a reaction space;
a substrate seating portion located in the reaction space; and
a rotational shaft portion comprising: a rotational shaft connected to a lower central region of the substrate seating portion; a connecting member in which an end of the rotational shaft is fixedly inserted; and a centering cap comprising a ring-shaped central body and a centering body which is located on the central body and having a cap inclination surface inclined downward, wherein the rotational shaft is tightly contacted to the cap inclination surface.

13. The substrate processing apparatus of claim 12, wherein the centering body comprises a sidewall surface extending from an outer surface of the central body and a cap inclination surface that is inclined downward from an end of the sidewall surface toward the upper surface of the central body; a shaft inclination surface corresponding to the cap inclination surface is provided at an end of the rotational shaft; the rotational shaft is formed of quartz; and the connecting member is formed of a SUS material.

14. The substrate processing apparatus of claim 12, further comprising a contacting member making the connecting member tightly coupled to the rotational shaft,
wherein at least one O-ring is used as the contacting member or the contacting member comprises a contacting body formed in a tube shape and an elastic portion provided on at least one of upper and lower portions of the contacting body, and
wherein the elastic portion is formed by cutting at least one of the upper and lower portions of the contacting body lengthwise into a plurality of cutting sections and bending the cutting sections of the contacting body at least once.

15. A substrate supporting apparatus comprising:
a substrate seating portion located in the reaction space; and
a rotational shaft portion comprising a rotational shaft connected to a lower central region of the substrate seating portion, a connecting member in which an end of the rotational shaft is fixedly inserted, a contacting member making the rotational shaft and the connecting shaft tightly coupled to each other, and an auxiliary member disposed between the rotational shaft and the connecting member,
wherein the rotational shaft comprises an upper supporting portion adjacent to an upper side of the connecting member, a lower supporting portion under the upper supporting portion, and an inclined supporting portion between the upper and lower supporting portions, wherein the rotational shaft in a region of the inclined supporting portion has a diameter that is gradually reduced downward.

16. The substrate supporting apparatus of claim 15, wherein the auxiliary member comprises an upper auxiliary portion contacted to the upper supporting portion, a lower auxiliary portion contacted to the lower supporting portion, an inclined auxiliary portion contacted to the inclined supporting portion, and a finishing auxiliary portion contacted to a lower portion of the rotational shaft, and
the rotational shaft comprises a dent portion provided on a lower portion of the rotational shaft and the auxiliary member comprises a coupling portion inserted and coupled into the dent portion.

17. A substrate supporting apparatus comprising:
a substrate seating portion located in the reaction space; and
a rotational shaft portion comprising: a rotational shaft connected to a lower central region of the substrate seating portion; a connecting member in which an end of the rotational shaft is fixedly inserted; a contacting member making the rotational shaft and the connecting shaft tightly coupled to each other, the contacting member comprising a tube-shaped contacting body and an elastic portion provided on at least one of upper and lower portions of the contacting body.

18. The substrate supporting apparatus of claim 17, wherein the rotational shaft is formed of quartz, the connecting member is formed of a SUS material, and the contacting member is formed of a same material as the connecting member,
wherein the elastic portion is formed by cutting at least one of the upper and lower regions of the contacting body lengthwise into a plurality of cutting sections and bending the cutting sections of the contacting body by at least ten times.

19. A substrate supporting apparatus comprising:
a substrate seating portion located in the reaction space; and
a rotational shaft portion comprising: a rotational shaft connected to a lower central region of the substrate seating portion; a connecting member in which an end of the rotational shaft is fixedly inserted; and a centering cap comprising a ring-shaped central body and a centering body which is located on the central body and having a cap inclination surface inclined downward, wherein the rotational shaft is tightly contacted to the cap inclination surface.

20. The substrate supporting apparatus of claim 19, further comprising a driving unit applying rotational force to the rotational shaft portion,
wherein the rotational shaft is formed of quartz, the connecting member is formed of a SUS material, and a shaft inclination surface corresponding to the cap inclination surface is provided at an end of the rotational shaft.
